(19) United States
(12) Patent Application Publication
(10) Pub. No.: US 2023/0213849 A1
(43) Pub. Date: Jul. 6, 2023

(54) BLANK MASK AND PHOTOMASK USING THE SAME

(71) Applicant: SKC solmics Co., Ltd., Pyeongtaek-si (KR)

(72) Inventors: GeonGon LEE, Seoul (KR); Suk Young CHOI, Seoul (KR); Hyung-joo LEE, Seoul (KR); SUNG HOON SON, Seoul (KR); Seong Yoon KIM, Seoul (KR); Min Gyo JEONG, Seoul (KR); Taewan KIM, Seoul (KR); INKYUN SHIN, Seoul (KR)

(73) Assignee: SKC solmics Co., Ltd., Pyeongtaek-si (KR)

(21) Appl. No.: 18/092,179

(22) Filed: Dec. 30, 2022

(30) Foreign Application Priority Data
Dec. 31, 2021 (KR) 10-2021-0194314
Oct. 14, 2022 (KR) 10-2022-0132122

(51) Int. Cl. G03F 1/48; G03F 1/60; G03F 1/80; G03F 7/004

(52) U.S. Cl. CPC G03F 1/48; G03F 1/60; G03F 1/80; G03F 7/0044

(57) ABSTRACT

A blank mask includes a transparent substrate and a light shielding film disposed on the transparent substrate. A surface of the light shielding film has a controlled power spectrum density value at a spatial frequency of 1 μm⁻¹ to 10 μm⁻¹. The surface of the light shielding film has a controlled minimum power spectrum density value at the spatial frequency of 1 μm⁻¹ to 10 μm⁻¹. An Rq value of the surface of the light shielding film is 0.25 nm to 0.55 nm.

### CROSS-REFERENCE TO RELATED APPLICATION

This application claims the benefit under 35 U.S.C. § 119(a) of Korean Patent Application No. 10-2021-0194314 filed on Dec. 31, 2021 and Korean Patent Application No. 10-2022-0132122 filed on Oct. 14, 2022, in the Korean Intellectual Property Office, the entire disclosure of which is incorporated herein by reference for all purposes.

### BACKGROUND

### 1. Field

The following description relates to a blank mask and a photomask using the same.

### 2. Description of Related Art

Due to high integration of semiconductor devices and the like, miniaturization of circuit patterns of the semiconductor devices is required. Accordingly, the importance of a lithography technique, which is a technique for developing a circuit pattern on a wafer surface using a photomask, is further emphasized.

In order to develop a miniaturized circuit pattern, a shorter wavelength of an exposure light source used in an exposure process is required. Exposure light sources used recently include an ArF excimer laser (with a wavelength of 193 nm) and the like.

Meanwhile, the photomask includes a binary mask, a phase shift mask, and the like.

The binary mask has a configuration in which a light shielding pattern layer is formed on a transparent substrate. In the binary mask, in order to expose a pattern on a resist film on a wafer surface, a light transmissive part that does not include a light shielding layer transmits exposure light, and a light shielding part including the light shielding layer blocks the exposure light from the surface on which the pattern is formed. However, in the binary mask, as the pattern becomes miniaturized, a problem may occur in developing of the miniaturized pattern due to diffraction of light generated at the edge of the light transmissive part in the exposure process.

The phase shift mask includes a Levenson type, an outrigger type, and a half-tone type. Among them, the half-tone type phase shift mask has a configuration in which a pattern formed of a semi-transmissive film is formed on a transparent substrate. In the half-tone type phase shift mask, a transmissive part not including a semi-transmissive layer transmits exposure light, and a semi-transmissive part including the semi-transmissive layer transmits attenuated exposure light at a surface in which the pattern is formed. The attenuated exposure light has a phase difference compared with the exposure light that has passed through the transmissive part. Due to this, diffracted light generated at the edge of the transmissive part is canceled by the exposure light that has passed through the semi-transmissive part, so that the phase shift mask can form a more delicate miniaturized pattern on the wafer surface.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a blank mask includes a transparent substrate and a light shielding film disposed on the transparent substrate.

The light shielding film may include a first light shielding layer and a second light shielding layer disposed on the first light shielding layer.

The second light shielding layer may include a transition metal and at least one of oxygen and nitrogen.

A surface of the light shielding film may have a power spectrum density value of 18 nm⁴ or more and 50 nm⁴ or less at a spatial frequency of 1 μm⁻¹ or more and 10 μm⁻¹ or less.

The surface of the light shielding film may have a minimum power spectrum density value of 18 nm⁴ or more and less than 40 nm⁴ at the spatial frequency of 1 μm⁻¹ or more and 10 μm⁻¹ or less.

An Rq value of the surface of the light shielding film may be 0.25 nm or more and 0.55 nm or less.

The Rq value may be a value evaluated by ISO_4287.

The surface of the light shielding film may have a maximum power spectrum density value of 28 nm⁴ or more and 50 nm⁴ or less at the spatial frequency of 1 μm⁻¹ or more and 10 μm⁻¹ or less.

The surface of the light shielding film may have a value of 70 nm⁴ or less obtained by subtracting a minimum value from a maximum value of the power spectrum density at the spatial frequency of 1 μm⁻¹ or more and 10 μm⁻¹ or less.

An etching rate of the second light shielding layer measured by etching with argon gas may be 0.3 Å/s or more and 0.5 Å/s or less.

An etching rate of the first light shielding layer measured by etching with argon gas may be 0.56 Å/s or more and 1 Å/s or less.

An etching rate of the light shielding film measured by etching with a chlorine-based gas may be 1.5 Å/s or more and 3 Å/s or less.

The second light shielding layer may include the transition metal of 30 at % or more and 80 at % or less, and the nitrogen of 5 at % or more and 30 at % or less.

The transition metal may include at least one of Cr, Ta, Ti and Hf, and may further include at least one of the transition metal of Group 7 to 12. The transition metal of groups 7 to 12 may include Mn, Fe, Co, Ni, Cu and Zn.

In another general aspect, a photomask includes a transparent substrate and a light shielding pattern film disposed on the transparent substrate.

The light shielding pattern film may include a first light shielding layer and a second light shielding layer disposed on the first light shielding layer.

The second light shielding layer may include a transition metal and at least one of oxygen and nitrogen.

An upper surface of the light shielding pattern film may have a power spectrum density value of 18 nm⁴ or more and 50 nm⁴ or less at a spatial frequency of 1 μm⁻¹ or more and 10 μm⁻¹ or less.

The upper surface of the light shielding pattern film may have a minimum power spectrum density value of 18 nm⁴ or more and less than 40 nm⁴ at the spatial frequency of 1 μm⁻¹ or more and 10 μm⁻¹ or less.

An Rq value of the upper surface of the light shielding pattern film may be 0.25 nm or more and 0.55 nm or less.

The Rq value may be a value evaluated by ISO_4287.

In another general aspect, a method of manufacturing a semiconductor device includes: disposing a light source, a photomask, and a semiconductor wafer coated with a resist film; selectively transmitting light incident from the light source through the photomask onto the semiconductor wafer; and developing a pattern on the semiconductor wafer.

The photomask may include a transparent substrate and a light shielding pattern film disposed on the transparent substrate.

The light shielding pattern film may include a first light shielding layer and a second light shielding layer disposed on the first light shielding layer.

The light shielding pattern film may include at least one of a transition metal, oxygen, and nitrogen.

An upper surface of the light shielding pattern film may have a power spectrum density value of 18 nm⁴ or more and 50 nm⁴ or less at a spatial frequency of 1 μm⁻¹ or more and 10 μm⁻¹ or less.

The upper surface of the light shielding pattern film may have a minimum power spectrum density value of 18 nm⁴ or more and less than 40 nm⁴ at the spatial frequency of 1 μm⁻¹ or more and 10 μm⁻¹ or less.

An Rq value of the upper surface of the light shielding pattern film may be 0.25 nm or more and 0.55 nm or less.

The Rq value may be a value evaluated by ISO_4287.

Other features and aspects will be apparent from the following detailed description, the drawings, and the claims.

### BRIEF DESCRIPTION OF DRAWINGS

The above and other objects, features and advantages of the present invention will become more apparent to those of ordinary skill in the art by describing in detail embodiments thereof with reference to the accompanying drawings, in which:

FIG. 1 illustrates a blank mask according to one or more embodiments of the present disclosure;

FIG. 2 illustrates a blank mask according to one or more embodiments of the present disclosure;

FIG. 3 illustrates a photomask according to one or more embodiments of the present disclosure;

FIG. 4 illustrates a graph disclosing power spectrum density measurement values according to spatial frequencies of Examples 1 to 5; and

FIG. 5 illustrates a graph disclosing power spectrum density measurement values according to spatial frequencies of Comparative Examples 1 to 3.

Throughout the drawings and the detailed description, the same reference numerals refer to the same elements. The drawings may not be to scale, and the relative size, proportions, and depiction of elements in the drawings may be exaggerated for clarity, illustration, and conveniences.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

An Rq value is a value evaluated based on ISO_4287. The Rq value means a root mean square height of the profile to be measured.

In the present specification, a pseudo defect is determined as a defect when inspected by a high-sensitivity defect inspection device, although it does not cause a reduction in resolution of a blank mask or photomask, so that it does not correspond to an actual defect.

As semiconductor devices are highly integrated, it is required to form a more miniaturized circuit pattern on a semiconductor wafer. As a line width of a pattern developed on the semiconductor wafer is further reduced, the line width of the pattern needs to be more finely and precisely controlled. Specifically, it may be required that a shape of a light shielding film patterned in a photomask has a shape closer to a designed pattern shape, and defects present on the surface of the light shielding film before and after patterning are more accurately detected and removed.

The inventors of one or more embodiments of the present disclosure confirmed that more delicate patterning of the light shielding film may be performed in a light shielding film having a two-layered structure through control of the power spectrum density and roughness characteristics. Further, the present inventors found that the frequency of detecting pseudo defects in a high-sensitivity defect inspection may decrease in this embodiment, and the inventors have completed this embodiment.

Hereinafter, one or more embodiments will be described in detail.

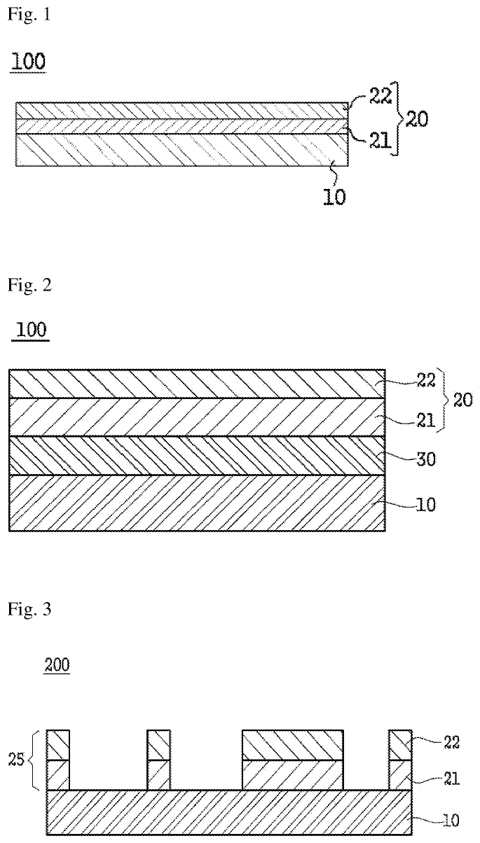

FIG. 1 illustrates a blank mask according to one or more embodiments of the present disclosure. The blank mask of the one or more embodiments will be described with reference to FIG. 1. Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

A blank mask 100 may include a transparent substrate 10 and a light shielding film 20 disposed on the transparent substrate 10.

The material of the transparent substrate 10 is not limited as long as it has light transmittance for exposure light, and may be applied to the blank mask 100. Specifically, transmittance of the transparent substrate 10 to exposure light having a wavelength of 193 nm may be 85% or more. The transmittance may be 87% or more. The transmittance may be 99.99% or less. For example, a synthetic quartz substrate may be applied as the transparent substrate 10. In this case, the transparent substrate 10 may suppress attenuation of light passing through the transparent substrate 10.

In addition, the transparent substrate 10 may suppress the occurrence of optical distortion by adjusting surface properties such as flatness and roughness.

The light shielding film 20 may be positioned on an upper surface of the transparent substrate 10.

The light shielding film 20 may have a characteristic of blocking at least a certain portion of the exposure light incident to a lower surface of the transparent substrate 10. In addition, when a phase shift film 30 (refer to FIG. 2) is positioned between the transparent substrate 10 and the light shielding film 20, the light shielding film 20 may be used as an etching mask in a process of etching the phase shift film 30 and the like in a pattern shape.

In one or more examples, the light shielding film 20 may include a first light shielding layer 21 and a second light shielding layer 22 disposed on the first light shielding layer 21.

The light shielding film 20 may include at least one of a transition metal, oxygen, and nitrogen.

The second light shielding layer may include a transition metal, and at least one of oxygen and nitrogen.

The first light shielding layer 21 and the second light shielding layer 22 may have different transition metal contents.

Power Spectrum Density and Roughness Characteristics of the Light Shielding Film

In one or more example, the surface of the light shielding film 20 has a power spectrum density value of 18 nm⁴ or more and 50 nm⁴ or less at a spatial frequency of 1 μm⁻¹ or more and 10 μm⁻¹ or less.

When an electron beam is irradiated to a resist film after forming the resist film on the light shielding film 20, electrons are accumulated on the surface of the light shielding film 20 under the resist film, and thus a charge-up phenomenon may occur. In this case, repulsion may occur between electrons included in the irradiated electron beam and electrons accumulated on the surface of the light shielding film 20, making it difficult to precisely control the shape of the resist pattern film.

According to one or more embodiments of the present disclosure, a grain boundary density on the surface of the light shielding film 20 may be controlled by controlling the power spectrum density of the surface of the light shielding film 20. Accordingly, electrons accumulated on the surface of the light shielding film 20 may move to a wider space, and thus the degree of charging of the surface of the light shielding film 20 caused by electron beam irradiation can be effectively reduced. At the same time, it is possible to suppress an increase in detection frequency of pseudo defects or a decrease in durability of the light shielding film 20 due to excessive grain growth.

The power spectrum density value at the surface of the light shielding film 20 may be measured through an atomic force microscope (AFM). Specifically, an area with a width of 1 μm and a length of 1 μm located at the center of the surface of the light shielding film 20 to be measured is measured using AFM in a non-contact mode. For example, the power spectrum density may be measured using the Park Systems' XE-150 model to which PPP-NCHR, a cantilever model of Park Systems, is applied as a probe.

The surface of the light shielding film 20 may have a power spectrum density value of 18 nm⁴ or more and 50 nm⁴ or less at a spatial frequency of 1 μm⁻¹ or more and 10 μm⁻¹ or less. The surface of the light shielding film 20 may have a power spectrum density value of 20 nm⁴ or more. The surface of the light shielding film 20 may have a power spectrum density value of 22 nm⁴ or more. The surface of the light shielding film 20 may have a power spectrum density value of 24 nm⁴ or more. The surface of the light shielding film 20 may have a power spectrum density value of 30 nm⁴ or more. The surface of the light shielding film 20 may have a power spectrum density value of 48 nm⁴ or less. The surface of the light shielding film 20 may have a power spectrum density value of 45 nm⁴ or less. The surface of the light shielding film 20 may have a power spectrum density value of 40 nm⁴ or less. In this case, the degree of charging of the surface of the light shielding film 20 by electron beam irradiation can be effectively reduced.

In one or more embodiments, the surface of the light shielding film 20 may have a maximum power spectrum density value of 28 nm⁴ or more and 50 nm⁴ or less at a spatial frequency of 1 μm⁻¹ or more and 10 μm⁻¹ or less. The maximum value of the surface of the light shielding film 20 may be 30 nm⁴ or more. The maximum value of the surface of the light shielding film 20 may be 35 nm⁴ or more. The maximum value of the surface of the light shielding film 20 may be 38 nm⁴ or more. The maximum value of the surface of the light shielding film 20 may be 48 nm⁴ or less. The maximum value of the surface of the light shielding film 20 may be 45 nm⁴ or less. The maximum value of the surface of the light shielding film 20 may be 40 nm⁴ or less. In this case, the size of the grains of the light shielding film 20 may be controlled to sufficiently reduce the repulsion between electrons on the surface of the light shielding film 20.

Further, in one or more embodiments, the surface of the light shielding film 20 may have a minimum power spectrum density value of 18 nm⁴ or more and less than 40 nm⁴ at a spatial frequency of 1 μm⁻¹ or more and 10 μm⁻¹ or less. The minimum value of the surface of the light shielding film 20 may be 20 nm⁴ or more. The minimum value of the surface of the light shielding film 20 may be 22 nm⁴ or more. The minimum value of the surface of the light shielding film 20 may be 24 nm⁴ or more. The minimum value of the surface of the light shielding film 20 may be 35 nm⁴ or less. The minimum value of the surface of the light shielding film 20 may be 33 nm⁴ or less. The minimum value of the surface of the light shielding film 20 may be 30 nm⁴ or less. The minimum value of the surface of the light shielding film 20 may be 28 nm⁴ or less. The minimum value of the surface of the light shielding film 20 may be 25 nm⁴ or less. The minimum value of the surface of the light shielding film 20 may be 23 nm⁴ or less. In this case, when the light shielding film 20 is patterned, a critical dimension (CD) error of the patterned light shielding film may be reduced, and when the surface of the light shielding film is inspected for defects with high sensitivity, the frequency of detecting pseudo defects may be reduced.

The surface of the light shielding film 20 may have a value of 70 nm⁴ or less obtained by subtracting the minimum value from the maximum value of the power spectrum density at a spatial frequency of 1 μm⁻¹ or more and 10 μm⁻¹ or less.

In one or more examples, the present disclosure may control a value obtained by subtracting the minimum value from the maximum value of the power spectrum density of the surface of the light blocking film 20 measured at a spatial frequency of 1 μm⁻¹ or more and 10 μm⁻¹ or less. Accordingly, by controlling the surface of the light shielding film 20 to have a relatively smooth shape, the detection frequency of pseudo defects can be effectively reduced in the high-sensitivity defect inspection of the light shielding film 20.

In one or more examples, the surface of the light shielding film 20 may have a value of 70 nm⁴ or less obtained by subtracting the minimum value from the maximum value of the power spectrum density at a spatial frequency of 1 μm⁻¹ or more and 10 μm⁻¹ or less. The value obtained by subtracting the minimum value from the maximum value may be 50 nm⁴ or less. The value obtained by subtracting the minimum value from the maximum value may be 30 nm⁴ or less. The value obtained by subtracting the minimum value from the maximum value may be 5 nm⁴ or more. The value obtained by subtracting the minimum value from the maximum value may be 8 nm⁴ or more. The value obtained by subtracting the minimum value from the maximum value may be 10 nm⁴ or more. In this case, when a high-sensitivity defect inspection is performed on the surface of the light shielding film 20, the accuracy of the inspection result may be further increased.

In one or more examples, an average value of a maximum value and a minimum value of power spectrum densities at a spatial frequency of 1 μm⁻¹ or more and 10 μm⁻¹ or less on the surface of the light shielding film 20 may be 15 nm⁴ or more. The average value may be 20 nm⁴ or more. The average value may be 25 nm⁴ or more. The average value may be 30 nm⁴ or more. The average value may be 100 nm⁴ or less. The average value may be 80 nm⁴ or less. The average value may be 60 nm⁴ or less. The average value may be 50 nm⁴ or less. The average value may be 45 nm⁴ or less. In this case, it is possible to stably control the intensity of charges formed on the surface of the light shielding film during electron beam irradiation.

In an example, an Rq value of the surface of the light shielding film 20 is 0.25 nm or more and 0.55 nm or less.

One or more embodiments of the present disclosure may simultaneously control the power spectrum density characteristics and the Rq value of the surface of the light shielding film 20. In this case, since the height of irregularities on the surface of the light shielding film formed by grain growth can be controlled, the frequency of pseudo defects detection can be reduced during high-sensitivity defect inspection, and the resist film can be precisely patterned by electron beam.

The Rq value is a value evaluated by ISO_4287. Specifically, the Rq value of the surface of the light shielding film 20 may be measured in a non-contact mode using an AFM in an area having a width of 1 μm and a length of 1 μm located at the center of the surface of the light shielding film 20 to be measured. For example, the Rq value may be measured using the Park Systems' XE-150 model to which PPP-NCHR, a cantilever model of Park Systems, is applied as a probe.

In one or more examples, Rq value of the surface of the light shielding film 20 may be 0.25 nm or more and 0.55 nm or less. The Rq value may be 0.27 nm or more. The Rq value may be 0.30 nm or more. The Rq value may be 0.45 nm or less. The Rq value may be 0.38 nm or less. In this case, the degree of formation of pseudo defects on the surface of the light shielding film 20 can be effectively reduced.

Etching Characteristics of the Light Shielding Film

In an example, an etching rate of the second light shielding layer 22 measured by etching with argon gas may be 0.3 Å/s or more and 0.5 Å/s or less.

In another example, an etching rate of the first light shielding layer 21 measured by etching with argon gas may be 0.56 Å/s or more.

In still another example, when the light shielding film 20 is dry-etched, a portion where the grain boundary is located may be etched at a relatively faster rate than an inside of the grain. In one or more embodiments, an etching rate for each layer of the light shielding film 20 may be adjusted by controlling the composition, grain boundary distribution, and the like for each layer in the light shielding film 20. Accordingly, it is possible to help a side surface of the patterned light shielding film to be formed more perpendicular to the surface of the substrate during the patterning of the light shielding film 20, and to suppress an excessive increase in roughness of the surface of the light shielding film 20 due to excessive growth of the grains in the light shielding film 20.

In an example of the present disclosure, an etching rate for each layer in the light shielding film 20 measured by etching with argon (Ar) gas may be adjusted. In an example, dry etching performed by applying argon gas as an etchant corresponds to physical etching that does not substantially involve a chemical reaction between the etchant and the light shielding film 20. In this case, an etching rate measured by using argon gas as an etchant is independent of the composition and chemical reactivity of each layer in the light shielding film 20, and is considered as a parameter that may effectively reflect the grain boundary density of each layer.

In an example, a method of measuring etching rates of the first light shielding layer 21 and the second light shielding layer 22 by etching with argon gas is as follows.

First, thicknesses of the first light shielding layer 21 and the second light shielding layer 22 may be measured using transmission electron microscopy (TEM). Specifically, a specimen is prepared by cutting the blank mask 100 into a size of 15 mm in width and 15 mm in length. After treating the surface of the specimen with a focused ion beam (FIB), the specimen is put into a TEM image measuring device, and the TEM image of the specimen is measured. Then, the thicknesses of the first light shielding layer 21 and the second light shielding layer 22 are calculated from the TEM image. For example, the TEM image may be measured using the JEM-2100F HR model of JEOL LTD.

Thereafter, the first light shielding layer 21 and the second light shielding layer 22 of the specimen are etched with argon gas to measure the time taken to etch each layer. Specifically, the specimen is put into an X-ray photoelectron spectroscopy (XPS) measuring device, and an area of 4 mm in width and 2 mm in length located in the center of the specimen is etched with argon gas to measure the etching time for each layer. When measuring the etching time, a vacuum level in the measuring device is 1.0*10⁻⁸ mbar, an X-ray source is monochromator Al Kα (1486.6 eV), an anode power is 72 W, an anode voltage is 12 kV, and a voltage of an argon ion beam is 1 kV. For example, Thermo Scientific's K-Alpha model may be applied as an XPS measuring device.

The etching rate of each layer measured by etching with argon gas may be calculated from the measured thicknesses and etching times of the first light shielding layer 21 and the second light shielding layer 22.

In one or more examples, the etching rate of the second light shielding layer 22 measured by etching with argon gas may be 0.3 Å/s or more and 0.5 Å/s or less. The etching rate may be 0.35 Å/s or more. The etching rate may be 0.5 Å/s or less. The etching rate may be 0.47 Å/s or less. The etching rate may be 0.45 Å/s or less. The etching rate may be 0.4 Å/s or less. In this case, it may help to more delicately pattern the light shielding film 20, and suppress an increase in the detection frequency of pseudo defects due to the surface roughness characteristics of the light shielding film 20.

In one or more examples, the etching rate of the first light shielding layer 21 measured by etching with argon gas may be 0.56 Å/s or more. The etching rate may be 0.58 Å/s or more. The etching rate may be 0.6 Å/s or more. The etching rate may be 1 Å/s or less. The etching rate may be 0.8 Å/s or less. In this case, when the light shielding film 20 is patterned, the side surface of the patterned light shielding film 20 can be helped to have a shape more perpendicular to the substrate surface, and the etching rate of the light blocking film 20 with respect to the etching gas may be maintained at a predetermined level or higher.

In accordance with one or more embodiments of the present disclosure, an etching rate of the light shielding film 20 measured by etching with a chlorine-based gas may be controlled. Accordingly, a thinner resist film can be applied when patterning the light shielding film 20, and a phenomenon in which the resist pattern film collapses during the patterning process of the light blocking film 20 can be suppressed.

In an example, a method of measuring an etching rate of the light shielding film 20 with a chlorine-based gas is as follows.

First, a thickness of the light shielding film 20 is measured by measuring a TEM image of the light shielding film 20. The method of measuring the thickness of the light shielding film 20 is the same as the method of measuring the first light shielding layer 21 and the like using TEM except for measuring the total thickness of the light shielding film 20.

Thereafter, the light shielding film 20 is etched with chlorine-based gas, and the etching time is measured. For chlorine-based gas, a gas containing 90 to 95 vol % of chlorine gas and 5 to 10 vol % of oxygen gas may be applied. The etching rate of the light shielding film 20 measured by etching with a chlorine-based gas may be calculated from the measured thickness and etching time of the light shielding film 20.

In one or more examples, the etching rate of the first light shielding layer 21 measured by etching with a chlorine-based gas may be 1.55 Å/s or more. The etching rate may be 1.6 Å/s or more. The etching rate may be 1.7 Å/s or more. The etching rate may be 3 Å/s or less. The etching rate may be 2 Å/s or less. In this case, the patterning of the light shielding film 20 may be performed more delicately by forming a relatively thin resist film.

Composition of the Light Shielding Film

In one or more embodiments, the process conditions and composition of the light shielding film 20 may be controlled in consideration of the power spectrum density characteristics, surface roughness characteristics, etching characteristics, and the like required for the light shielding film 20.

In an example, the content of each element in each layer of the light shielding film 20 may be confirmed through depth profile measurement using X-ray photoelectron spectroscopy (XPS). Specifically, a specimen is prepared by cutting the blank mask 100 into a size of 15 mm in width and 15 mm in length. Thereafter, the specimen is placed in the XPS measuring device, and an area of 4 mm in width and 2 mm in length positioned at the center of the sample is etched to measure the content of each element in each layer.

For example, the content of each element in each thin film may be measured using the Thermo Scientific's K-alpha model.

In an example, the first light shielding layer 21 may include a transition metal, oxygen, and nitrogen. The first light shielding layer 21 may include 15 at % or more of the transition metal. The first light shielding layer 21 may include 20 at % or more of the transition metal. The first light shielding layer 21 may include 25 at % or more of the transition metal. The first light shielding layer 21 may include 30 at % or more of the transition metal. The first light shielding layer 21 may include 50 at % or less of the transition metal. The first light shielding layer 21 may include 45 at % or less of the transition metal. The first light shielding layer 21 may include 40 at % or less of the transition metal.

In one or more examples, a value of the sum of the oxygen content and the nitrogen content of the first light shielding layer 21 may be 23 at % or more. The value may be 32 at % or more. The value may be 37 at % or more. The value may be 70 at % or less. The value may be 65 at % or less. The value may be 60 at % or less.

In one or more examples, the first light shielding layer 21 may include 20 at % or more of oxygen. The first light shielding layer 21 may include 25 at % or more of oxygen. The first light shielding layer 21 may include 30 at % or more of oxygen. The first light shielding layer 21 may include 50 at % or less of oxygen. The first light shielding layer 21 may include 45 at % or less of oxygen. The first light shielding layer 21 may include 40 at % or less of oxygen.

In one or more examples, the first light shielding layer 21 may include 3 at % or more of nitrogen. The first light shielding layer 21 may include 7 at % or more of nitrogen. The first light shielding layer 21 may include 20 at % or less of nitrogen. The first light shielding layer 21 may include 15 at % or less of nitrogen.

In one or more examples, the first light shielding layer 21 may include 5 at % or more of carbon. The first light shielding layer 21 may include 10 at % or more of carbon. The first light shielding layer 21 may include 25 at % or less of carbon. The first light shielding layer 21 may include 20 at % or less of carbon.

In this case, the first light shielding layer 21 may help the light shielding film 20 to have excellent light extinction characteristics, and may contribute to performing more delicate patterning of the light shielding film 20.

In one or more examples, the second light shielding layer 22 may include a transition metal, and at least one of oxygen and nitrogen. The second light shielding layer 22 may include 30 at % or more of the transition metal. The second light shielding layer 22 may include 35 at % or more of the transition metal. The second light shielding layer 22 may include 40 at % or more of the transition metal. The second light shielding layer 22 may include 45 at % or more of the transition metal. The second light shielding layer 22 may include 80 at % or less of the transition metal. The second light shielding layer 22 may include 75 at % or less of the transition metal. The second light shielding layer 22 may include 70 at % or less of the transition metal. The second light shielding layer 22 may include 65 at % or less of the transition metal.

In one or more examples, a value of the sum of the oxygen content and the nitrogen content of the second light shielding layer 22 may be 10 at % or more. The value may be 15 at % or more. The value may be 25 at % or more. The value may be 70 at % or less. The value may be 65 at % or less. The value may be 60 at % or less. The value may be 55 at % or less. The value may be 50 at % or less.

In one or more examples, the second light shielding layer 22 may include 5 at % or more of oxygen. The second light shielding layer 22 may include 10 at % or more of oxygen. The second light shielding layer 22 may include 15 at % or more of oxygen. The second light shielding layer 22 may include 40 at % or less of oxygen. The second light shielding layer 22 may include 35 at % or less of oxygen. The second light shielding layer 22 may include 30 at % or less of oxygen. The second light shielding layer 22 may include 25 at % or less of oxygen.

In one or more examples, the second light shielding layer 22 may include 5 at % or more of nitrogen. The second light shielding layer 22 may include 10 at % or more of nitrogen. The second light shielding layer 22 may include 30 at % or less of nitrogen. The second light shielding layer 22 may include 25 at % or less of nitrogen.

In one or more examples, the second light shielding layer 22 may include 1 at % or more of carbon. The second light shielding layer 22 may include 5 at % or more of carbon. The second light shielding layer 22 may include 25 at % or less of carbon. The second light shielding layer 22 may include 20 at % or less of carbon.

In this case, when the surface of the light shielding film 20 is irradiated with an electron beam, it may help prevent excessive charge formation on the surface of the light shielding film 20. In addition, when the surface of the light shielding film 20 is inspected for defects with high sensitivity, it may help reduce the detection frequency of pseudo defects.

In one or more examples, the absolute value of a value obtained by subtracting the transition metal content of the first light shielding layer 21 from the transition metal content of the second light shielding layer 22 may be 3 at % or more. The absolute value may be 10 at % or more. The absolute value may be 15 at % or more. The absolute value may be 40 at % or less. The absolute value may be 35 at % or less. The absolute value may be 30 at % or less.

In one or more examples, the absolute value of a value obtained by subtracting the oxygen content of the first light shielding layer 21 from the oxygen content of the second light shielding layer 22 may be 3 at % or more. The absolute value may be 10 at % or more. The absolute value may be 15 at % or more. The absolute value may be 30 at % or less. The absolute value may be 25 at % or less.

In one or more examples, the absolute value of a value obtained by subtracting the nitrogen content of the first light shielding layer 21 from the nitrogen content of the second light shielding layer 22 may be 1 at % or more. The absolute value may be 5 at % or more. The absolute value may be 30 at % or less. The absolute value may be 20 at % or more.

In this case, the etching rate of each layer of the light shielding film 20 may be easily adjusted within a preset range in this embodiment.

In an example, the transition metal may include at least one of Cr, Ta, Ti, and Hf. The transition metal may be Cr.

In another example, the transition metal may further include a transition metal of Group 7 to 12.

The inventors of one or more embodiments of the present disclosure have experimentally confirmed that when the light shielding film 20 contains a small amount of a Group 7 to 12 transition metal element, the size of grains such as chromium is controlled within a certain range during a heat treatment process. This is considered to be because when the grains grow through heat treatment, the Group 7 to 12 transition metal elements act as impurities and may hinder the continuous growth of the grain boundaries. According to one or more embodiments, the power spectrum density and roughness characteristics of the light shielding film 20 are controlled within a range preset in one or more embodiments of the present disclosure by including a small amount of Group 7 to 12 transition metal elements in the light shielding film 20.

For example, Group 7 to 12 transition metal may include Mn, Fe, Co, Ni, Cu, Zn, and the like. In an example, Group 7 to 12 transition metal may be Fe.

Thickness of the Light Shielding Film

In one or more examples, the thickness of the first light shielding layer 21 may be 250 to 650 Å. The thickness of the first light shielding layer 21 may be 350 to 600 Å. The thickness of the first light shielding layer 21 may be 400 to 550 Å.

In this case, it is possible to help the first light shielding layer 21 to have excellent light extinction characteristics.

In one or more examples, the thickness of the second light shielding layer 22 may be 30 to 200 Å. The thickness of the second light shielding layer 22 may be 30 to 100 Å. The thickness of the second light shielding layer 22 may be 40 to 80 Å. In this case, the light shield film 20 may be patterned more delicately, so that the resolution of the photomask may be further improved.

In one or more examples, the ratio of the thickness of the second light shielding layer 22 to the thickness of the first light shielding layer 21 may be 0.05 to 0.3. The thickness ratio may be 0.07 to 0.25. The thickness ratio may be 0.1 to 0.2. In this case, the side shape of the light shielding pattern film formed through patterning may be more delicately controlled.

Optical Properties of the Light Shielding Film

In one or more examples, the optical density of the light shielding film 20 for light having a wavelength of 193 nm may be 1.3 or more. The optical density of the light shielding film 20 for light having a wavelength of 193 nm may be 1.4 or more.

In one or more examples, the transmittance of the light shielding film 20 with respect to light having a wavelength of 193 nm may be 2% or less. The transmittance of the light shielding film 20 with respect to light having a wavelength of 193 nm may be 1.9% or less.

In this case, the light shielding film 20 may help effectively block transmission of exposure light.

In an example, the optical density and transmittance of the light shielding film 20 may be measured using a spectroscopic ellipsometer. For example, the optical density and transmittance of the light blocking film 20 may be measured using the NanoView's MG-Pro model.

Other Thin Films

FIG. 2 illustrates a blank mask according to one or more embodiments of the present disclosure. The following contents will be described with reference to FIG. 2.

In an example, a phase shift film 30 may be disposed between the transparent substrate 10 and the light shielding film 20. The phase shift film 30 is a thin film that attenuates the light intensity of exposure light passing through the phase shift film 30 and substantially suppresses diffracted light generated at the edge of the transfer pattern by adjusting the phase difference of the exposure light.

In an example, the phase difference of the phase shift film 30 with respect to light having a wavelength of 193 nm may be 170 to 190°. The phase difference of the phase shift film 30 with respect to light having a wavelength of 193 nm may be 175 to 185°.

In an example, the transmittance of the phase shift film 30 with respect to light having a wavelength of 193 nm may be 3 to 10%. The transmittance of the phase shift film 30 with respect to light having a wavelength of 193 nm may be 4 to 8%.

In this case, diffracted light that may be generated at the edge of the pattern film may be effectively suppressed.

In one or more examples, the optical density of a thin film including the phase shift film 30 and the light shielding film 20 for light having a wavelength of 193 nm may be 3 or more. The optical density of a thin film including the phase shift film 30 and the light shielding film 20 for light having a wavelength of 193 nm may be 5 or less. In this case, the thin film may effectively suppress the transmission of exposure light.

The phase difference and transmittance of the phase shift film 30, and the optical density of the thin film including the phase shift film 30 and the light shielding film 20 may be measured using a spectroscopic ellipsometer. For example, as the spectroscopic ellipsometer, the NanoView's MG-Pro model may be used.

In an example, the phase shift film 30 may include a transition metal and silicon. The phase shift film 30 may include a transition metal, silicon, oxygen, and nitrogen. For example, the transition metal may be molybdenum.

In an example, a hard mask (not shown) may be positioned on the light shielding film 20. The hard mask may function as an etching mask film when the pattern of the light shielding film 20 is etched. The hard mask may include silicon, nitrogen, and oxygen.

In an example, a resist film (not shown) may be positioned on the light shielding film. The resist film may be formed in contact with an upper surface of the light shielding film. The resist film may be formed in contact with an upper surface of another thin film disposed on the light shielding film.

The resist film may form a resist pattern film through electron beam irradiation and development. The resist pattern film may function as an etching mask film when the pattern of the light shielding film 20 is etched.

In an example, a positive resist may be applied as the resist film. In another example, a negative resist may be applied as the resist film. For example, as the resist film, the Fuji's FEP255 model may be applied.

Photomask

FIG. 3 illustrates a photomask according to one or more embodiments of the present disclosure. The following contents will be described with reference to FIG. 3.

According to one or more embodiments of the present specification, a photomask 200 includes a transparent substrate 10 and a light shielding pattern film 25 disposed on the transparent substrate 10.

In an example, the light shielding pattern film 25 may include a first light shielding layer 21 and a second light shielding layer 22 disposed on the first light shielding layer 21. The second light shielding layer includes a transition metal, and at least one of oxygen and nitrogen.

In one or more examples, an upper surface of the light shielding pattern film has a power spectrum density value of 18 nm⁴ or more and 50 nm⁴ or less at a spatial frequency of 1 μm⁻¹ or more and 10 μm⁻¹ or less. The upper surface of the light shielding pattern film has a minimum power spectrum density value of 18 nm⁴ or more and less than 40 nm⁴ at a spatial frequency of 1 μm⁻¹ or more and 10 μm⁻¹ or less.

In an example, an Rq value of the upper surface of the light shielding pattern film is 0.25 nm or more and 0.55 nm or less. The Rq value is a value evaluated by ISO_4287.

The description of the transparent substrate 10 included in the photomask 200 is omitted because it overlaps with the above description.

The light shielding pattern film 25 may be formed by patterning the light shielding film 20 described above. The description of the layer structure, physical properties, composition, and the like of the light shielding pattern film 25 overlaps with the previous description of the light shielding film 20 and thus will be omitted.

Manufacturing Method of the Light Shielding Film

A method of manufacturing a blank mask according to one or more embodiments of the present specification includes: a preparation operation of disposing a sputtering target including a transition metal and a transparent substrate in a sputtering chamber, a first light shielding layer formation operation of forming a first light shielding layer on the transparent substrate; a second light shielding layer formation operation of forming a second light shielding layer on the first light shielding layer to manufacture a light shielding film; and a heat treatment operation of heat treating the light shielding film.

In the preparation operation, a sputtering target including a transition metal may be selected when the light shielding film is formed in consideration of the composition of the light shielding film.

In one or more examples, the sputtering target may include at least one of Cr, Ta, Ti, and Hf in an amount of 90 wt % or more. The sputtering target may include at least one of Cr, Ta, Ti, and Hf in an amount of 95 wt % or more. The sputtering target may include at least one of Cr, Ta, Ti, and Hf in an amount of 99 wt % or more.

Further, the sputtering target may include 90 wt % or more of Cr. The sputtering target may include 95 wt % or more of Cr. The sputtering target may include 99 wt % or more of Cr. The sputtering target may include 99.9 wt % or more of Cr. The sputtering target may include 99.97 wt % or more of Cr. The sputtering target may include 100 wt % or less of Cr.

In another example, the sputtering target may further include Group 7 to 12 transition metals. Examples of Group 7 to 12 transition metals include Mn, Fe, Co, Ni, Cu, Zn, and the like. For example, Group 7 to 12 transition metal may be Fe.

In one or more examples, the sputtering target may include 0.0001 wt % or more of Group 7 to 12 transition metal elements. The sputtering target may include 0.001 wt % or more of Group 7 to 12 transition metal elements. The sputtering target may include 0.003 wt % or more of Group 7 to 12 transition metal elements. The sputtering target may include 0.005 wt % or more of Group 7 to 12 transition metal elements. The sputtering target may include 0.035 wt % or less of Group 7 to 12 transition metal elements. The sputtering target may include 0.03 wt % or less of Group 7 to 12 transition metal elements. The sputtering target may include 0.025 wt % or less of Group 7 to 12 transition metal elements. In this case, the grain boundary density of the light shielding film formed by applying the target may be adjusted to lower the degree of charge formation on the surface of the light shielding film due to electron beam irradiation, and the effect of grain growth on the surface roughness characteristics of the light shielding film may be reduced.

The content of each element in the sputtering target may be confirmed by measuring using inductively coupled plasma-optical emission spectrometry (ICP-OES). For example, the content of each element in the sputtering target may be measured by Seiko Instruments' ICP-OES.

In the preparation operation, a magnet may be placed in the sputtering chamber. The magnet may be disposed at a surface opposite to one surface on which sputtering occurs in the sputtering target.

In the first light shielding layer formation operation and the second light shielding layer formation operation, different sputtering process conditions may be applied to each layer included in the light shielding film. Specifically, various process conditions such as atmosphere gas composition, power applied to the sputtering target, and film formation time may be differently applied to each layer in consideration of the power spectrum density characteristics, surface roughness characteristics, light extinction characteristics, etching characteristics, and the like required for each layer.

In an example, the atmosphere gas may include an inert gas and a reactive gas. The inert gas is a gas that does not include an element constituting the formed film and/or layer. The reactive gas is a gas that includes an element constituting the formed film and/or layer.

For example, the inert gas may include a gas that is ionized in a plasma atmosphere and collides with the target. The inert gas may include argon. The inert gas may further include helium for purposes such as stress control of a thin film to be formed.

In one or more examples, the reactive gas may include a gas including a nitrogen element. The gas including the nitrogen element may be, for example, N₂, NO, NO₂, N₂O, N₂O₃, N₂O₄, N₂O₅ and the like. The reactive gas may include a gas including an oxygen element. The gas including the oxygen element may be, for example, O₂, CO₂ and the like. Further, the reactive gas may include a gas including a nitrogen element and a gas including an oxygen element. The reactive gas may include a gas including both nitrogen and oxygen elements. The gas including both the nitrogen and oxygen elements may be, for example, NO, NO₂, N₂O, N₂O₃, N₂O₄, N₂O₅ and the like.

In an example, a sputtering gas may be an Ar gas.

In an example, as a power source for applying power to the sputtering target, a DC power source or an RF power source may be used.

Next, in the first light shielding layer formation operation, the power applied to the sputtering target may be applied in a range of 1.5 kW or more and 2.5 kW or less. The power applied to the sputtering target may be applied in a range of 1.6 kW or more and 2 kW or less.

In one or more examples, in the first light shielding layer formation operation, a ratio of the flow rate of the reactive gas to the flow rate of the inert gas of the atmosphere gas may be 0.5 or more. The ratio of the flow rate may be 0.7 or more. The ratio of the flow rate may be 1.5 or less. The ratio of the flow rate may be 1.2 or less. The ratio of the flow rate may be 1 or less.

In the atmosphere gas, a ratio of an argon gas flow rate to a total inert gas flow rate may be 0.2 or more. in one or more examples, the ratio of the flow rate may be 0.25 or more. The ratio of the flow rate may be 0.3 or more. The ratio of the flow rate may be 0.55 or less. The ratio of the flow rate may be 0.5 or less. The ratio of the flow rate may be 0.45 or less.

In one or more examples, in the atmosphere gas, a ratio of an oxygen content to a nitrogen content included in the reactive gas may be 1.5 or more and 4 or less. The ratio may be 1.8 or more and 3.8 or less. The ratio may be 2 or more and 3.5 or less.

In this case, the formed first light shielding layer may help the light shielding film to have sufficient light quenching properties. In addition, it may help to precisely control the shape of the light shielding pattern film in the light shielding film patterning process.

In an example, the first light shielding layer may be formed for a period of 200 seconds or more and 300 seconds or less. The first light shielding layer may be formed for a period of 230 seconds or more and 280 seconds or less. In this case, the formed first light shielding layer may help the light shielding film to have sufficient light extinction characteristics.

In one or more examples, in the second light shielding layer formation operation, the power applied to the sputtering target may be applied in a range of 1 to 2 kW. The power may be applied in a range of 1.2 to 1.7 kW. In this case, it may help the second light shielding layer to have desired optical properties and etching properties.

In one or more examples, the second light shielding layer formation operation may be performed after 15 seconds or more from immediately after forming a film or a layer (e.g., the first light shielding layer) disposed in contact with a lower surface of the second light shielding layer. The second light shielding layer formation operation may be performed after 20 seconds or more from immediately after forming a film or a layer disposed in contact with the lower surface of the second light shielding layer. The second light shielding layer formation operation may be performed within 30 seconds from immediately after forming a film or a layer disposed in contact with the lower surface of the second light shielding layer.

In another example, the second light shielding layer formation operation may be performed after completely exhausting an atmosphere gas applied to the formation of a film or a layer (e.g., the first light shielding layer) disposed in contact with the lower surface of the second light shielding layer from the sputtering chamber. The second light shielding layer formation operation may be performed within 10 seconds from the time when the atmosphere gas applied to the formation of a film or a layer disposed in contact with the lower surface of the second light shielding layer is completely exhausted. The second light shielding layer formation operation may be performed within 5 seconds from the time when the atmosphere gas applied to the formation of a film or a layer disposed in contact with the lower surface of the second light shielding layer is completely exhausted.

In this case, the composition of the second light shielding layer may be more precisely controlled.

Further, in one or more examples, in the second light shielding layer formation operation, a ratio of the flow rate of the reactive gas to the flow rate of the inert gas included in the atmosphere gas may be 0.4 or more. The ratio of the flow rate may be 0.5 or more. The ratio of the flow rate may be 0.65 or more. The ratio of the flow rate may be 1 or less. The ratio of the flow rate may be 0.9 or less. The ratio of the flow rate may be 0.8 or less.

In one or more examples, in the atmosphere gas, a ratio of the flow rate of the argon gas to the total inert gas may be 0.8 or more. The ratio of the flow rate may be 0.9 or more. The ratio of the flow rate may be 0.95 or more. The ratio of the flow rate may be 1 or less.

Yet further, in the second light shielding layer formation operation, the oxygen content ratio to the nitrogen content included in the reactive gas may be 0.3 or less. The ratio may be 0.1 or less. The ratio may be 0 or more. The ratio may be 0.001 or more.

In this case, it is possible to help the light shielding film surface to have power spectrum density and roughness characteristics in a range preset in one or more embodiments.

Further, the second light shielding layer formation operation may be performed for a period of 10 seconds or more and 30 seconds or less. The second light shielding layer formation operation may be performed for a period of 15 seconds or more and 25 seconds or less. In this case, when the light shielding pattern film is formed through dry etching, the shape of the light shielding pattern film may be more precisely controlled.

In the heat treatment operation, the light shielding film may be heat-treated. After the substrate on which the light shielding film is formed is disposed in a heat treatment chamber, the light shielding film may be heat-treated. In accordance with one or more embodiments, the internal stress of the light shielding film may be relieved by performing the heat treatment on the formed light shielding film, and the size of the grains formed through recrystallization may be adjusted.

In the heat treatment operation, an atmosphere temperature in the heat treatment chamber may be 150° C. or higher. In one or more examples, the atmosphere temperature may be 200° C. or higher. The atmosphere temperature may be 250° C. or higher. The atmosphere temperature may be 400° C. or less. The atmosphere temperature may be 350° C. or less.

The heat treatment operation may be performed for 5 minutes or more according to one or more examples. The heat treatment operation may be performed for 10 minutes or more. The heat treatment operation may be performed for 60 minutes or less. The heat treatment operation may be performed for 45 minutes or less. The heat treatment operation may be performed for 25 minutes or less.

In this case, the degree of grain growth of the light shielding film may be controlled so that the surface of the light shielding film has power spectrum density and roughness characteristics within a range preset in one or more embodiments.

The method of manufacturing a blank mask according to one or more embodiments of the present disclosure may further include a cooling operation of cooling the light shielding film after the heat treatment has been completed. During the cooling operation, a cooling plate may be installed on the side of the transparent substrate to cool the light shielding film.

In an example, a distance between the transparent substrate and the cooling plate may be 0.05 mm or more and 2 mm or less. A cooling temperature of the cooling plate may be 10° C. or more and 40° C. or less. The cooling operation may be performed for 5 minutes or more and 20 minutes or less.

In this case, continuous growth of grains due to residual heat of the light shielding film after heat treatment may be effectively suppressed.

Semiconductor Device Manufacturing Method

According to one or more embodiments of the present disclosure, a method of manufacturing a semiconductor device includes: a preparation operation of disposing a light source, a photomask, and a semiconductor wafer coated with a resist film; an exposure operation of selectively transmitting the light incident from the light source through the photomask onto the semiconductor wafer; and a development operation of developing a pattern on the semiconductor wafer.

The photomask may include a transparent substrate and a light shielding pattern film disposed on the transparent substrate.

The light shielding pattern film may include a first light shielding layer and a second light shielding layer disposed on the first light shielding layer.

The light shielding pattern film may include at least one of a transition metal, oxygen, and nitrogen.

An upper surface of the light shielding pattern film has a power spectrum density value of 18 nm⁴ or more and 50 nm⁴ or less at a spatial frequency of 1 μm⁻¹ or more and 10 μm⁻¹ or less.

The upper surface of the light shielding film has a minimum power spectrum density value of 18 nm⁴ or more and less than 40 nm⁴ at a spatial frequency of 1 μm⁻¹ or more and 10 μm⁻¹ or less.

An Rq value of the upper surface of the light shielding pattern film is 0.25 nm or more and 0.55 nm or less. The Rq value is a value evaluated by ISO_4287.

In the preparation operation, the light source may be a device capable of generating an exposure light having a short wavelength. The exposure light may be light having a wavelength of 200 nm or less. The exposure light may be ArF light having a wavelength of 193 nm.

In an embodiment, a lens may be further disposed between the photomask and the semiconductor wafer. The lens has a function of reducing the shape of a circuit pattern on the photomask and transferring it onto the semiconductor wafer. The lens is not limited as long as it may be generally applied to an ArF semiconductor wafer exposure process. For example, the lens may be a lens made of calcium fluoride (CaF₂).

In the exposure operation, the exposure light may be selectively transmitted onto the semiconductor wafer through the photomask. In this case, chemical transformation may occur in a portion of the resist film to which the exposure light is incident.

In the development operation, a pattern may be developed on the semiconductor wafer by performing a developer treatment on the semiconductor wafer after the exposure operation. When the applied resist film is a positive resist, a portion of the resist film to which the exposure light is incident may be dissolved by the developer. When the applied resist film is a negative resist, a portion of the resist film to which the exposure light is not incident may be dissolved by the developer. The resist film is formed into a resist pattern by the developer treatment. A pattern may be formed on the semiconductor wafer using the resist pattern as a mask.

The description of the photomask is omitted because it overlaps with the previous description.

Hereinafter, specific examples will be described in more detail.

### Manufacturing Example: Formation of Light Shielding Film

### Example 1: In a Chamber of a DC Sputtering Device, a Quartz-Based Transparent

substrate having a width of 6 inches, a length of 6 inches, a thickness of 0.25 inches, and a flatness of less than 500 nm was disposed. A sputtering target having the composition shown in Table 1 below was placed in the chamber so that a T/S distance was 255 mm and an angle between the substrate and the target was 25 degrees. A magnet was installed at the rear surface of the sputtering target.

Thereafter, a first light shielding layer was formed by introducing an atmosphere gas in which Ar 19 vol %, N₂ 11 vol %, CO₂ 36 vol %, and He 34 vol % were mixed in the chamber, applying power of 1.85 kW to the sputtering target, applying magnet rotation speed of 113 rpm, and performing a sputtering process for 250 seconds.

After the formation of the first light shielding layer, a second light shielding layer was formed by introducing an atmosphere gas in which Ar 57 vol % and N₂ 43 vol % were mixed on the first light shielding layer in the chamber, applying power of 1.5 kW to the sputtering target, applying magnet rotation speed of 113 rpm, and performing a sputtering process for 25 seconds.

A specimen on which the formation of the second light shielding layer was completed was placed in the heat treatment chamber. Thereafter, heat treatment was performed for 15 minutes at an ambient temperature of 250° C.

After that, a cooling plate having a cooling temperature of 10 to 40° C. was installed on a substrate side of a blank mask that had undergone heat treatment, and cooling treatment was performed. A distance between the substrate of the blank mask and the cooling plate was set to 0.1 mm. The cooling treatment was performed for 5 to 20 minutes.

Example 2: A blank mask specimen was prepared under the same conditions as in Example 1 except that, in the preparation operation, a sputtering target was disposed as a target having the composition shown in Table 1 below, and, an ambient temperature of 300° C. was applied for the heat treatment operation.

Examples 3 to 5 and Comparative Examples 1 to 3: blank mask specimens were prepared under the same conditions as in Example 1 except that, in the preparation operation, sputtering targets were disposed as targets having the compositions shown in Table 1 below.

The composition of the sputtering target applied for each example and comparative example is described in Table 1 below.

### Evaluation Example: Power Spectrum Density Measurement

Power spectrum density values of the specimens of Examples and Comparative Examples were measured using an AFM.

The power spectrum density value at the surface of the light shielding film was measured using the Park Systems' XE-150 model to which PPP-NCHR, a cantilever model of Park Systems, was applied as a probe. Specifically, an area with a width of 1 μm and a length of 1 μm located in the center of the surface of the light shielding film to be measured was measured using AFM in a non-contact mode. When measuring the power spectrum density, the spatial frequency was set in a range of 1 μm⁻¹ or more and 10 μm⁻¹ or less.

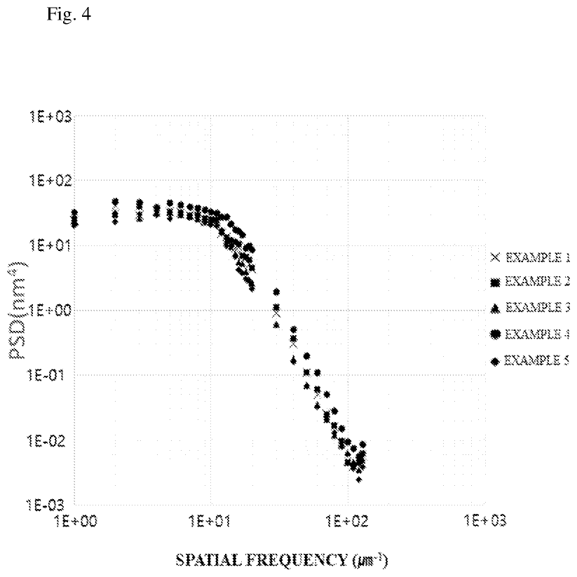

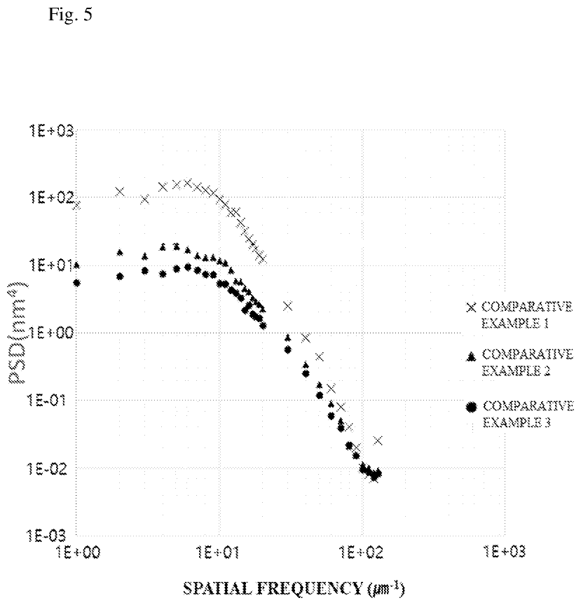

FIGS. 4 and 5 illustrate graphs disclosing power spectrum density measurement values according to spatial frequencies of Examples 1 to 5 and Comparative Examples 1 to 3, respectively, in accordance with one or more embodiments. Maximum and minimum values of the power spectrum density at the spatial frequency of 1 μm⁻¹ or more and 10 μm⁻¹ or less for each Example and Comparative Example are shown in Table 2 below.

### Evaluation Example: Rq Value Measurement

According to ISO_4287, an Rq value of the specimens for each Example and Comparative Example was measured.

The power spectrum density value at the surface of the light shielding film was measured using the Park Systems' XE-150 model to which PPP-NCHR, a cantilever model of Park Systems, was applied as a probe. Specifically, measurement was performed in a non-contact mode in an area with a width of 1 μm and a length of 1 μm located in the center of the surface of the light shielding film to be measured using AFM.

The measurement results for each Example and Comparative Example are shown in Table 2 below.

### Evaluation Example: Evaluation of Frequency of Detection of Pseudo Defects

Defect inspection was performed by taking out specimens for each Example and Comparative Example stored in a standard mechanical interface pod (SMIF pod). Specifically, on the surface of the light shielding film of the specimen, a region having a width of 146 mm and a length of 146 mm located at the center of the surface of the light shielding film was specified as a measurement site.

Next, defect inspection was performed on the measurement site using the Lasertec's M6641S model with an inspection light wavelength of 532 nm, a laser power of 0.4 or more and 0.5 or less, and a stage speed of 2 based on setting values in the equipment.

Thereafter, by measuring the image of the measurement site, among the result values according to the defect inspection for each Example and Comparative Example, the results corresponding to pseudo defects were distinguished and listed in Table 2 below.

### Evaluation Example: Evaluation of Whether Light Shielding Pattern Film is Defective

After a resist film was formed on an upper surface of the light shielding film of the specimen of each Example and Comparative Example, contact hole patterns were formed in the center of the resist film using an electron beam. The contact hole patterns consisted of a total of 156 contact hole patterns, 13 in a horizontal direction and 12 in a vertical direction.

Thereafter, an image of the patterned resist film surface for each specimen was measured. For each specimen, when the number of contact hole patterns detected as defective was 5 or less, it was evaluated as X, and when the number was 6 or more, it was evaluated as O.

The evaluation results for each Example and Comparative Example are shown in Table 2 below.

### Evaluation Example: Measurement of Etching Characteristics of the Light Shielding Film

Two specimens of Example 1 were each processed to have a size of 15 mm in width and 15 mm in length. After the surface of the processed specimen was treated with a focused ion beam (FIB), it was placed in the JEM-2100F HR model of JEOL LTD, and a TEM image of the specimen was measured. Thicknesses of the first light shielding layer and the second light shielding layer were calculated from the TEM image.

Thereafter, for one specimen of Example 1, the time required for etching the first light shielding layer and the second light shielding layer with argon gas was measured. Specifically, the specimen was placed in Thermo Scientific's K-Alpha model, and an area with a width of 4 mm and a length of 2 mm located in the center of the specimen was etched with argon gas to measure the etching time for each layer. When measuring the etching time for each layer, a vacuum level in the measuring device is 1.0*10⁻⁸ mbar, an X-ray source is monochromator Al Kα (1486.6 eV), an anode power is 72 W, an anode voltage is 12 kV, and a voltage of an argon ion beam is 1 kV.

The etching rate for each layer was calculated from the measured thicknesses and etching times of the first light shielding layer and the second light shielding layer.

The other specimen of Example 1 was etched with a chlorine-based gas to measure the time required to etch the entire light shielding film. As the chlorine-based gas, a gas including 90 to 95 vol % of chlorine gas and 5 to 10 vol % of oxygen gas was applied. The etching rate of the light shielding film with respect to the chlorine-based gas was calculated from the thickness of the light shielding film and the etching time of the light shielding film.

The etching rate measurement values for the argon gas and chlorine-based gas of Example 1 are shown in Table 3 below.

### Evaluation Example: Measurement of the Composition of Each Thin Film

The content of each element in each layer in the light shielding film of Example 1 and Comparative Example 1 was measured using XPS analysis. Specifically, blank masks of Example 1 and Comparative Example 1 were processed into sizes of 15 mm in width and 15 mm in length to prepare specimens. After the specimen was placed in the Thermo Scientific's K-Alpha model measuring equipment, an area of 4 mm in width and 2 mm in length located in the center of the specimen was etched to measure the content of each element in each layer. The measurement results of Example 1 and Comparative Example 1 are shown in Table 4 below.

TABLE 1

| | Elemental content of sputtering target | | | | | |
|---|---|---|---|---|---|---|
| | Cr | C | O | N | Fe | |
| | (wt %) | (wt %) | (wt %) | (wt %) | (wt %) | weight(g) |
| Example 1 | 99.985 | 0.002 | 0.009 | 0.001 | 0.003 | 0.040 |
| Example 2 | 99.985 | 0.002 | 0.009 | 0.001 | 0.003 | 0.040 |
| Example 3 | 99.983 | 0.002 | 0.009 | 0.001 | 0.005 | 0.067 |
| Example 4 | 99.988 | 0.001 | 0.009 | 0.001 | 0.001 | 0.013 |
| Example 5 | 99.978 | 0.002 | 0.009 | 0.001 | 0.010 | 0.134 |
| Comparative | 99.988 | 0.002 | 0.009 | 0.001 | 0.000 | 0.000 |
| Example 1 | | | | | | |
| Comparative | 99.948 | 0.002 | 0.009 | 0.001 | 0.040 | 1.073 |
| Example 2 | | | | | | |
| Comparative | 99.908 | 0.003 | 0.008 | 0.001 | 0.080 | 1.073 |
| Example 3 | | | | | | |

TABLE 2

| | Measurement results | | | | | | |
|---|---|---|---|---|---|---|---|
| | Power spectrum density | | | | | | |
| | (Spatial frequency 1~10 μm⁻¹ condition) | | | | | | |
| | | | | Average of | | Number of | Light |
| | | | Maximum | maximum | | pseudo | shielding |
| | Maximum | Minimum | minus | and | | defects | pattern film |
| | value | value | minimum | minimum | Rq | detected | defective |
| Division | (nm⁴) | (nm⁴) | (nm⁴) | (nm⁴) | (nm) | (ea) | or not |
| Example 1 | 39.8 | 24.7 | 15.1 | 32.25 | 0.369 | 47 | X |
| Example 2 | 39.9 | 24.9 | 15.0 | 32.40 | 0.374 | 45 | X |
| Example 3 | 32.6 | 23.1 | 9.5 | 27.85 | 0.296 | 26 | X |
| Example 4 | 47.6 | 32.5 | 15.1 | 40.05 | 0.437 | 67 | X |
| Example 5 | 30.4 | 20.3 | 10.1 | 25.35 | 0.271 | 12 | X |
| Comparative | 162.0 | 76.8 | 85.2 | 119.40 | 0.557 | 515 | X |
| Example 1 | | | | | | | |
| Comparative | 17.0 | 10.3 | 6.7 | 13.65 | 0.215 | 8 | ◯ |
| Example 2 | | | | | | | |
| Comparative | 9.5 | 5.4 | 4.1 | 7.45 | 0.145 | 2 | ◯ |
| Example 3 | | | | | | | |

TABLE 3

| | Etching rate (Å/s) | Etching rate (Å/s) | |
|---|---|---|---|
| | of the first light | of the second light | Etching rate (Å/s) |
| | shielding layer | shielding layer | of the light |
| | measured | measured | blocking film |
| | by etching | by etching | measured by a |
| | with argon gas | with argon gas | chlorine-based gas |
| Example 1 | 0.621 | 0.430 | 1.7 |

TABLE 4

| | | Cr(at %) | C(at %) | N(at %) | O(at %) |
|---|---|---|---|---|---|
| Example 1 | Second light | 57.4 | 10.9 | 16.0 | 15.7 |
| | shielding | | | | |
| | layer | | | | |
| | First light | 39.3 | 14.9 | 9.7 | 36.1 |
| | shielding | | | | |
| | layer | | | | |
| Comparative | Second light | 57.2 | 10.5 | 16.3 | 15.9 |
| Example 1 | shielding | | | | |
| | layer | | | | |
| | First light | 39.6 | 14.7 | 9.4 | 36.3 |
| | shielding | | | | |
| | layer | | | | |

Referring to Table 2, the number of pseudo defects detected in Examples 1 to 5 was measured to be 100 or less, whereas in Comparative Example 1, it was measured to be more than 500.

In the evaluation of whether the light shielding pattern film was defective, Examples 1 to 5 were evaluated as X, whereas Comparative Examples 2 and 3 were evaluated as O.

Referring to Table 3, each etching rate measurement value of Example 1 was measured to be included within the range defined by the embodiment.

When patterning a blank mask and the like according to one or more embodiments of the present disclosure, a higher resolution pattern can be formed. In addition, a more accurate defect inspection result can be obtained when a high-sensitivity defect inspection for a light shielding film of the blank mask is performed.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A blank mask comprising:
a transparent substrate; and
a light shielding film disposed on the transparent substrate,
wherein:
the light shielding film comprises a first light shielding layer and a second light shielding layer disposed on the first light shielding layer,
the second light shielding layer comprises a transition metal and at least one of oxygen and nitrogen,
a surface of the light shielding film has a power spectrum density value of 18 nm⁴ or more and 50 nm⁴ or less at a spatial frequency of 1 μm⁻¹ or more and 10 μm⁻¹ or less,
the surface of the light shielding film has a minimum power spectrum density value of 18 nm⁴ or more and less than 40 nm⁴ at the spatial frequency of 1 μm⁻¹ or more and 10 μm⁻¹ or less, and
an Rq value of the surface of the light shielding film is 0.25 nm or more and 0.55 nm or less, and the Rq value is a value evaluated by ISO_4287.

2. The blank mask of claim 1, wherein the surface of the light shielding film has a maximum power spectrum density value of 28 nm⁴ or more and 50 nm⁴ or less at the spatial frequency of 1 μm⁻¹ or more and 10 μm⁻¹ or less.

3. The blank mask of claim 1, wherein the surface of the light shielding film has a value of 70 nm⁴ or less obtained by subtracting a minimum value from a maximum value of the power spectrum density at the spatial frequency of 1 μm⁻¹ or more and 10 μm⁻¹ or less.

4. The blank mask of claim 1, wherein an etching rate of the second light shielding layer measured by etching with argon gas is 0.3 Å/s or more and 0.5 Å/s or less.

5. The blank mask of claim 1, wherein an etching rate of the first light shielding layer measured by etching with argon gas is 0.56 Å/s or more and 1 Å/s or less.

6. The blank mask of claim 1, wherein an etching rate of the light shielding film measured by etching with a chlorine-based gas is 1.5 Å/s or more and 3 Å/s or less.

7. The blank mask of claim 1, wherein the second light shielding layer comprises the transition metal of 30 at % or more and 80 at % or less, and the nitrogen of 5 at % or more and 30 at % or less.

8. The blank mask of claim 1, wherein the transition metal comprises at least one of Cr, Ta, Ti and Hf, and further comprises at least one of the transition metal of groups 7 to 12.

9. The blank mask of claim 8, wherein the transition metal of groups 7 to 12 includes Mn, Fe, Co, Ni, Cu and Zn.

10. A photomask comprising:
a transparent substrate; and
a light shielding pattern film disposed on the transparent substrate,
wherein:
the light shielding pattern film comprises a first light shielding layer and a second light shielding layer disposed on the first light shielding layer,
the second light shielding layer comprises a transition metal and at least one of oxygen and nitrogen,
an upper surface of the light shielding pattern film has a power spectrum density value of 18 nm⁴ or more and 50 nm⁴ or less at a spatial frequency of 1 μm⁻¹ or more and 10 μm⁻¹ or less,
the upper surface of the light shielding pattern film has a minimum power spectrum density value of 18 nm⁴ or more and less than 40 nm⁴ at the spatial frequency of 1 μm⁻¹ or more and 10 μm⁻¹ or less, and
an Rq value of the upper surface of the light shielding pattern film is 0.25 nm or more and 0.55 nm or less, and the Rq value is a value evaluated by ISO_4287.

11. The photomask of claim 10, wherein the upper surface of the light shielding pattern film has a maximum power spectrum density value of 28 nm⁴ or more and 50 nm⁴ or less at the spatial frequency of 1 μm⁻¹ or more and 10 μm⁻¹ or less.

12. The photomask of claim 10, wherein the upper surface of the light shielding pattern film has a value of 70 nm⁴ or less obtained by subtracting a minimum value from a maximum value of the power spectrum density at the spatial frequency of 1 μm⁻¹ or more and 10 μm⁻¹ or less.

13. The photomask of claim 10, wherein an etching rate of the second light shielding layer measured by etching with argon gas is 0.3 Å/s or more and 0.5 Å/s or less.

14. The photomask of claim 10, wherein an etching rate of the first light shielding layer measured by etching with argon gas is 0.56 Å/s or more and 1 Å/s or less.

15. The photomask of claim 10, wherein an etching rate of the light shielding pattern film measured by etching with a chlorine-based gas is 1.5 Å/s or more and 3 Å/s or less.

16. The photomask of claim 10, wherein the second light shielding layer comprises the transition metal of 30 at % or more and 80 at % or less, and the nitrogen of 5 at % or more and 30 at % or less.

17. The photomask of claim 10, wherein the transition metal comprises at least one of Cr, Ta, Ti and Hf, and further comprises at least one of the transition metal of groups 7 to 12.

18. The photomask of claim 17, wherein the transition metal of groups 7 to 12 includes Mn, Fe, Co, Ni, Cu and Zn.

19. A method of manufacturing a semiconductor device, the method comprising:
disposing a light source, a photomask, and a semiconductor wafer coated with a resist film;
selectively transmitting light incident from the light source through the photomask onto the semiconductor wafer; and
developing a pattern on the semiconductor wafer, wherein:
the photomask comprises a transparent substrate and a light shielding pattern film disposed on the transparent substrate,
the light shielding pattern film comprises a first light shielding layer and a second light shielding layer disposed on the first light shielding layer,
the light shielding pattern film comprises at least one of a transition metal, oxygen, and nitrogen,
an upper surface of the light shielding pattern film has a power spectrum density value of 18 nm⁴ or more and 50 nm⁴ or less at a spatial frequency of 1 μm⁻¹ or more and 10 μm⁻¹ or less,
the upper surface of the light shielding pattern film has a minimum power spectrum density value of 18 nm⁴ or more and less than 40 nm⁴ at the spatial frequency of 1 μm⁻¹ or more and 10 μm⁻¹ or less, and
an Rq value of the upper surface of the light shielding pattern film is 0.25 nm or more and 0.55 nm or less, and the Rq value is a value evaluated by ISO_4287.
